(19) United States
(12) Patent Application Publication
(10) Pub. No.: US 2009/0224954 A1
(43) Pub. Date: Sep. 10, 2009

(54) Active-Passive Continuous-Time Sigma-Delta Analog-to-Digital Converter Having Improved Linearity and Reduced Power Consumption

(75) Inventor: Ganesh K. Balachandran, Irving, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/042,398

(22) Filed: Mar. 5, 2008

(51) Int. Cl. H03M 1/34

(52) U.S. Cl. 341/158

(57) ABSTRACT

An active-passive continuous-time analog-to-digital converter and a method of continuous-time sigma-delta analog-to-digital conversion. In certain embodiments, the converter has a reduced power consumption, and the method requires less power to carry out. One embodiment of the converter has a signal input and includes: (1) an input summing junction coupled to the signal input, (2) a folded cascode transconductor having an input coupled to the input summing junction and (3) a feedforward path that couples the signal input to at least two nodes within the folded cascode transconductor.

### TECHNICAL FIELD OF THE INVENTION

The invention is directed, in general, to analog-to-digital converters (ADCs) and, more specifically, to an active-passive continuous-time sigma-delta ADC having improved linearity and reduced power consumption and a method of continuous-time sigma-delta analog-to-digital conversion.

### BACKGROUND OF THE INVENTION

Mobile telephone technology has greatly advanced in recent years, as evident by the higher performance digital mobile telephones now available. To a large extent, these advances stem from the widespread deployment of modern digital wireless modulation technologies, such as time division multiple access (TDMA), code division multiple access (CDMA) technologies including conventional CDMA, wideband CDMA (WCDMA), and CDMA2000 standards and personal communications service (PCS) modulation. The carrier frequencies for these modulated signals ranges from on the order of 800 MHz to as high as 2.0 GHz. These and other digital modulation and communications techniques have greatly improved wireless telephone services, at reduced cost to the consumer. All of the aforementioned technologies require that signals be converted from analog to digital form.

An analog input signal can be converted into a digital output word using an analog-to-digital converter (ADC), also called an analog-to-digital modulator (ADM), which contains a mixture of analog and digital circuitry. The speed, resolution and linearity of the conversion affect the accuracy with which the digital output word represents the analog input signal. The conversion speed must be high enough to sample the shortest analog input signal period (highest analog signal frequency) at least twice. The number of bits in the digital output word determines the conversion resolution and has to be large enough to resolve the maximum peak-to-peak analog input signal into a required degree of granularity. The conversion linearity has to be sufficient to operate at or preferably below a required maximum level of distortion associated with the conversion process.

Several different algorithms and architectures exist that may be employed to accomplish a conversion. These include sigma-delta, successive approximation, pipeline and flash ADCs in increasing order of bandwidth capability. Of particular interest is the sigma-delta ADC, which typically provides a reasonable trade-off between sampling rate and bits of resolution while providing a low component count that benefits cost of production, size and reliability.

The sigma-delta ADC employs sigma-delta modulation techniques that digitize an input signal using very low resolution (one-bit) and a very high sampling rate (often in the megahertz range). Oversampling and the use of digital filters increases the resolution to as many as twenty or more bits. It is especially useful for high resolution conversion of low to moderate frequency signals as well as low distortion conversion of signals containing audio frequencies due to its inherent qualities of good linearity and high accuracy.

In its basic form, the sigma-delta ADC employs an input modulator and an output digital filter and decimator. The input modulator operates by accepting an input signal through an input summing junction, which feeds a loop filter. The loop filter basically provides an integrated value of this signal to a comparator, which acts as a one-bit quantizer. The comparator output signal is fed back to the input summing junction through a circuit that acts as a one-bit digital-to-analog converter (DAC). The feedback loop forces the average of the feedback signal to be substantially equal to the input signal. The density of “ones” in the comparator output signal is proportional to the value of the input signal. The input modulator oversamples the input signal by clocking the comparator at a rate that is much higher than the Nyquist rate. Then, the output digital filter and decimator produce output data words at a data rate appropriate to the conversion.

ADCs may operate in discrete time or continuous time. Continuous-time ADCs are advantageous in that the loop filter is better able to handle aliasing, which becomes more problematic with higher input signal frequencies. An active-passive sigma-delta ADC (APADC) is a type of sigma-delta ADC that employs a passive integrator before the input summing junction and an active integrator after the input summing junction and therefore within the loop filter. While current APADC designs are quite effective at analog-to-digital conversion, they can always benefit from improvements. What is particularly needed in the art is an improved continuous-time APADC.

### SUMMARY OF THE INVENTION

To address the above-discussed deficiencies of the prior art, one aspect of the invention provides an active-passive continuous-time analog-to-digital converter that may exhibit a reduced power consumption. One embodiment of the converter has a signal input and includes: (1) an input summing junction coupled to the signal input, (2) a folded cascode transconductor having an input coupled to the input summing junction and (3) a feedforward path that couples the signal input to at least two nodes within the folded cascode transconductor.

Another aspect of the invention is a method of continuous-time sigma-delta analog-to-digital conversion that may require less power to carry out. One embodiment of the method includes: (1) receiving an input signal into a signal input, (2) receiving the input signal into an input summing junction coupled to the signal input, (3) receiving the input signal into a folded cascode transconductor having an input coupled to the input summing junction and (4) employing a feedforward path to provide an attenuated form of the input signal to at least two nodes within the folded cascode transconductor.

### BRIEF DESCRIPTION OF THE DRAWINGS

For a more complete understanding of the invention, reference is now made to the following descriptions taken in conjunction with the accompanying drawings, in which:

FIG. 1 is a block diagram of one embodiment of a single-ended continuous-time APADC including a feedforward path;

FIG. 2 is a block diagram of one embodiment of a differential continuous-time APADC including a feedforward path;

FIG. 3 is a block diagram of one embodiment of a folded cascode transconductor in the differential continuous-time APADC of FIG. 2;

FIG. 4 is a graph illustrating an example of signal excursions at the input summing junction experienced without and with a feedforward path to nodes within a folded cascode transconductor;

FIG. 5 is a graph illustrating an example of APADC output without a feedforward path to a transconductor;

FIG. 6 is a graph illustrating an example of APADC output with a feedforward path to a transconductor; and

FIG. 7 is a flow diagram of one embodiment of a method of operating an active-passive continuous-time sigma-delta ADC.

### DETAILED DESCRIPTION

As stated above, an APADC is a type of sigma-delta ADC that employs a passive integrator before the input summing junction and an active integrator after the input summing junction and therefore within the loop filter. Because APADCs find wide use in battery-powered devices, such as mobile telephones, power consumption is an ongoing concern. Unfortunately, the active integrator consumes a substantial portion of the power required to operate the overall APADC (approximately 75% in one example). This is because the transistors in a folded cascode transconductor in the active integrator need to maintain a gate-to-source voltage margin over threshold voltage, V_{gst}, sufficient to maintain substantial linearity over an expected range of input signal levels.

Noise constraints and loop filter characteristics determine the transconductance, Gm, that the folded cascode transconductor needs to have to provide suitable performance. The following equation relates Gm to V_{gst}:

$$Gm = \frac{2 I}{{V}_{GST}} ,$$

where I is the current the folded cascode transconductor requires to provide the needed Gm. From this equation it is apparent that, for example, I must double to double Gm. For this reason, it is highly desirable to reduce the input signal range provided to the folded cascode transconductor; both Gm and I can be reduced as a result. Battery-powered devices benefit from the lower overall current draw and are able to operate a longer period of time on a charge.

The conventional way to address the problem is to reduce the input signal range by increasing the value of the input capacitor that is part of the passive integrator. Unfortunately, the capacitor that results is relatively large and substantially increases the overall silicon area the APADC requires. It also has no effect on the amount of transconductor thermal noise the loop filter feeds back to the input summing junction; consequently the signal-to-noise ratio (SNR) of the APADC decreases.

Feedforward paths may also be used to compensate for an excessive input signal range. Feedforward paths of various types have been used in discrete-time ADCs and fully-active continuous-time ADCs. In the latter case, the feedforward path uses a feedforward resistor to couple the voltage input to the output of the active integrator. Unfortunately, if this same path is employed in a continuous-time APACD, the feedforward resistor loads the output of the active integrator, which decreases the gain of the loop filter, particularly with respect to lower frequencies which contain most of the signal. As a result, the SNR of the APACD rises to an unacceptable level for most applications.

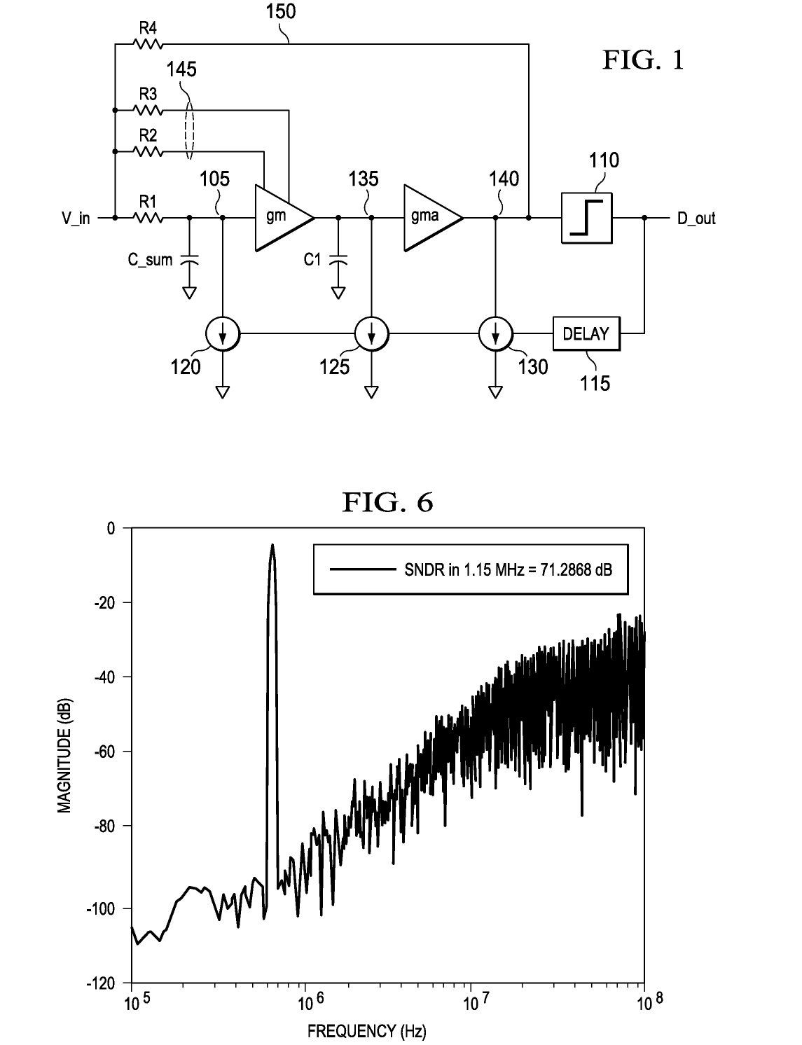

Introduced herein is a new feedforward path that not only compensates for an excessive input range but avoids loading the output of the active integrator. FIG. 1 is a block diagram of one embodiment of a single-ended continuous-time APADC including such a feedforward path. A signal input V_in is configured to receive an input signal of varying voltage. In one embodiment, the voltage varies in the range of about ±1.00 volts. An input resistor R1 and an input capacitor C_sum are coupled between V_in and an input summing junction 110 and serve as a passive integrator for the input signal. In one embodiment, the input resistor R1 has a resistance value of about 25 kΩ, and the input capacitor C_sum has a capacitance value of about 19.2 pF. The input summing junction 110 is part of a loop filter of the ADC. An input of a folded cascode transconductor gm is coupled to the output of the input summing junction 110, and a capacitor C1 is coupled to the output of the folded cascode transconductor gm. In one embodiment, the capacitor C1 has a capacitance value of about 9.6 pF. The folded cascode transconductor gm and capacitor C1 serve as an active integrator for the input signal.

An input of a transconductance amplifier gma is also coupled to the output of the folded cascode transconductor gm. The transconductance amplifier gma amplifies the integrated current provided by the folded cascode transconductor gm. An input of a comparator 120 is coupled to an output of the transconductance amplifier gma. The comparator 120 acts as a one-bit quantizer for the amplified, integrated current provided by the transconductance amplifier gma. The output of the comparator 120, which is a one or a zero, is provided at a data output D_out and also fed back to an input of a delay circuit 130. In one embodiment, the delay circuit 130 introduces a delay of about e^{-sTclk/2} (where Tclk is the period of the clock signal that drives the sigma-delta ADC, and s is the Laplace operator), which is about half a clock cycle.

Current sources 140, 150, 160, which act as DACs, are coupled to an output of the delay circuit 130. The current source 140 is coupled to the input summing junction 110. The current source 150 is coupled to a node 170 between the output of the folded cascode transconductor gm and the input of the transconductance amplifier gma. The current source 160 is coupled to a node 180 between the output of the transconductance amplifier gma and the input of the comparator 120. Depending upon the sign of the output of the delay circuit 130, the current sources 140, 150, 160 either add or subtract currents from the input summing node 110, the node 170 and the node 180. The current source 140 adds or subtracts a current I_{ref1}, the current source 150 adds or subtracts a current I_{ref2}, and the current source 160 adds or subtracts a current I_{ref3}.

A feedforward path 145 that includes feedforward resistors R2, R3 couples the signal input V_in to at least two nodes within the folded cascode transconductor gm. As will be described, the feedforward path introduces an attenuated form of the input signal to the at least two nodes to reduce the input signal range that the transistors in the folded cascode transconductor must accommodate. As a result, V_{gst} can be reduced, which means I, the current required to power the folded cascode transconductor, can be reduced without having to sacrifice substantial linearity over an expected range of input signal levels. In one embodiment, R2 has a resistance value equal to about

$$\frac{{V}_{in\_MAX}}{{I}_{ref 2}} ,$$

where Vᵢₙ_{_{—}}_{MAX} is a maximum expected value of an input signal to be provided to the signal input V_in, and R3=R2.

FIG. 1 illustrates an optional second feedforward path 150. The second feedforward path 150 includes a feedforward resistor R4 and couples the signal input V_in to the node 180 between the output of the transconductance amplifier gma and the input of the comparator 120. In one embodiment, R4 has a resistance value equal to about

$$\frac{{V}_{in\_MAX}}{ref 3} .$$

The second feedforward path 150 is optional for two reasons. First, the benefit the second feedforward path 150 yields is substantially less than the benefit the feedforward path 145 yields. Second, the node 180 is sensitive to changes in impedance, including changes in parasitic impedance. The second feedforward path 150 does introduce parasitic impedance, especially capacitance, to the node 180. Therefore, one embodiment includes the second feedforward path 150, another embodiment omits it. Still other embodiments may include further feedforward or feedback paths. Those skilled in the pertinent art are familiar with APADCs and how their performance may be modified or enhanced by various feedforward or feedback paths.

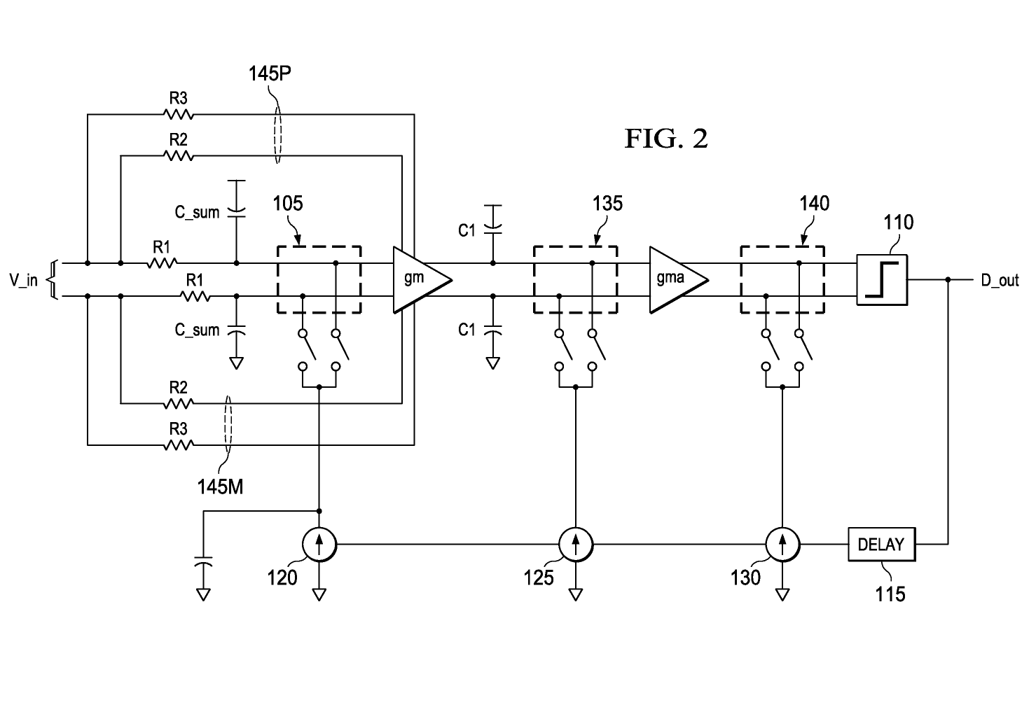

FIG. 2 is a block diagram of one embodiment of a differential continuous-time APADC including a feedforward path. FIG. 2 differs from FIG. 1 in two respects. First, the second feedforward path 150 of FIG. 1 is omitted. Second, the APADC of FIG. 2 is differential as opposed to single-ended. Differential APADCs tend to exhibit greater linearity than single-ended APADCs.

The signal input V_in has a positive rail and a negative rail. Each rail has an input resistor R1 and an input capacitor C_sum preceding the input summing junction 110. Both rails pass through the folded cascode transconductor gm. Each rail has a capacitor C1 at the node 170. Both rails also pass through the transconductance amplifier gma and the comparator 120. The output of the comparator 120, which is still a one or a zero, is provided at the data output D_out and also fed back to the delay circuit 130. The current sources 140, 150, 160, are coupled to the input summing junction 110, the node 170 and the node 180, respectively. The current sources 140, 150, 160, are coupled to the positive or the negative rail at those points depending upon the sign of the output of the delay circuit 130, which drives respective unreferenced switches interposing the current sources 140, 150, 160 and the input summing node 110, the node 170 and the node 180 respectively.

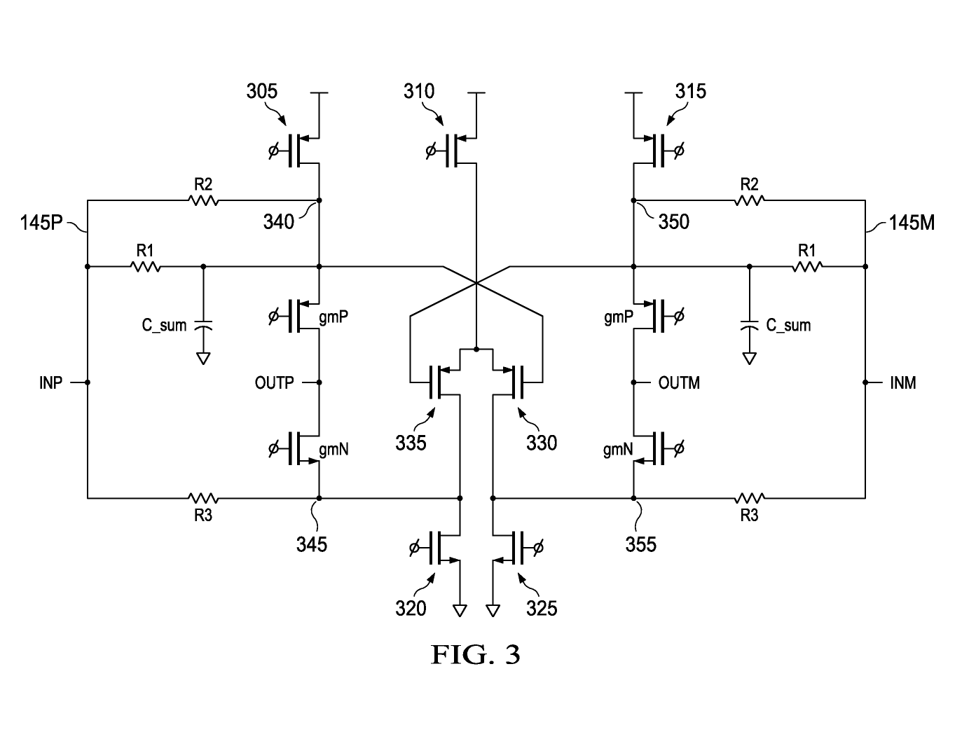

A feedforward path exists for each of the positive rail and the negative rail. The feedforward path 145P couples the positive rail of the signal input V_in to two nodes within the folded cascode transconductor gm; the feedforward path 145M couples the negative rail of the signal input V_in to another two nodes within the folded cascode transconductor gm. FIG. 3 will show these nodes within the folded cascode transconductor gm in detail.

FIG. 3 is a block diagram of one embodiment of a folded cascode transconductor gm in the differential continuous-time APADC of FIG. 2. A folded cascode transconductor gm for the single-ended continuous-time APADC of FIG. 1 would be a single-ended version of the folded cascode transconductor gm of FIG. 2.

The folded cascode transconductor gm employs three current sources 305, 310, 315 at a head thereof and two current sinks 320, 325 at a tail thereof. A pair of transistors 330, 335 receives an input signal received at inputs INP, INM via R1 and C_sum. Transistors gmP, gmN establish voltage intermediate the current sources 305, 310, 315, 320, 325 and provide at internal nodes therebetween outputs OUTP, OUTM as shown. As those skilled in the art understand, the folded cascode transconductor gm produces an output current at the outputs OUTP, OUTM that is a function of an input voltage presented at the inputs INP, INM.

Of particular note to the present discussion are the feedforward paths 145P, 145M for the positive and negative rails, each with their respective feedforward resistors R2, R3. The feedforward path 145P is shown as coupling INP to an internal node 340 via the feedforward resistor R2 and an internal node 345 via the feedforward resistor R3. The feedforward path 145M is shown as coupling INM to an internal node 350 via the feedforward resistor R2 and an internal node 355 via the feedforward resistor R3. The feedforward paths introduce an attenuated form of the input signal to the internal nodes 340, 345, 350, 355 to reduce the input signal range that the transistors in the folded cascode transconductor must accommodate.

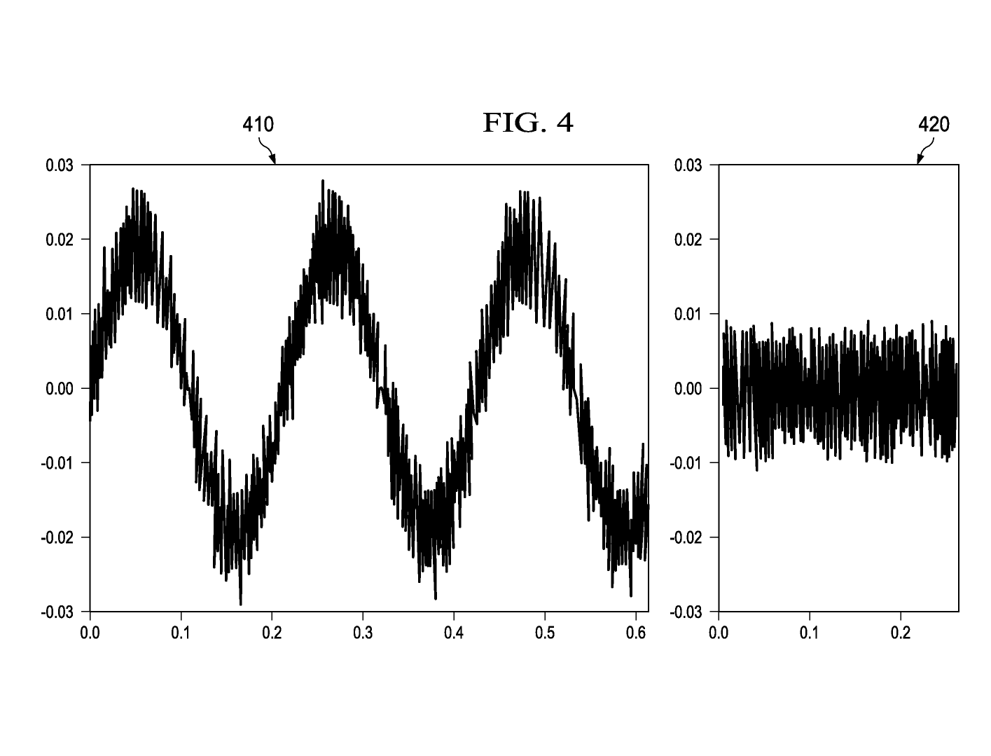

FIG. 4 is a graph illustrating an example of signal excursions at the input summing junction experienced without (a signal 410) and with (a signal 420) a feedforward path to nodes within a folded cascode transconductor. The signal 410 has a larger sinusoidal component and a smaller transconductor thermal noise component superposed thereon. It is apparent from the scale on the Y-axis that the signal range is ±0.03V, or a little less than 0.06V peak-to-peak. In contrast, the sinusoidal component of the signal 420 has been decreased markedly. Although the superposed thermal noise component remains, the signal range with the feedforward path to nodes within a folded cascode transconductor is now about ±0.01V, or a little less than 0.02V peak-to-peak. In this example, the input signal range provided to the folded cascode transconductor has been reduced to about one-third of its original value. Transconductor and therefore overall APADC current draw can therefore be similarly reduced without sacrificing linearity.

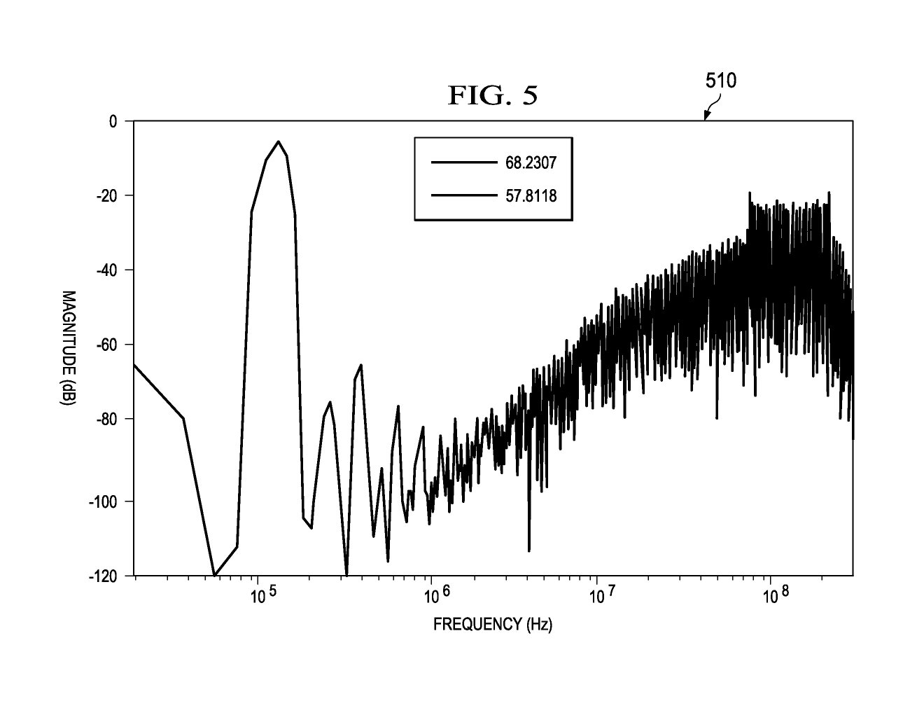

FIG. 5 is a graph illustrating an example of APADC output without a feedforward path to a transconductor. A −6 dB input signal was used. A significant third harmonic 510 results from nonlinearity in the APADC. The third harmonic, which is difficult to filter, is only 58 dB below the fundamental frequency. It is desirable not to have a third harmonic this large.

FIG. 6 is a graph illustrating an example of APADC output with a feedforward path to a transconductor. It can be seen that the prominent third harmonic of FIG. 5 is now substantially attenuated, indicating that the linearity of the APADC has been increased.

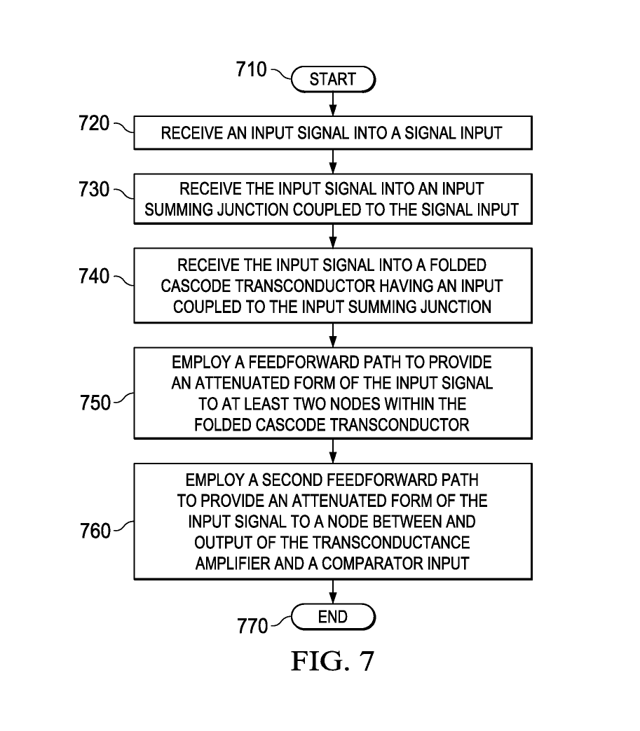

FIG. 7 is a flow diagram of one embodiment of a method of operating a continuous-time APADC. The method begins in a start step 710. In a step 720, an input signal is received into a signal input. In a step 730, the input signal is received into an input summing junction coupled to the signal input. In a step 740, the input signal is received into a folded cascode transconductor having an input coupled to the input summing junction. In a step 750, a feedforward path is employed to provide an attenuated form of the input signal to at least two nodes within the folded cascode transconductor. If the continuous-time APADC is a differential continuous-time APADC, the employing of the step 750 comprises employing the feedforward path to provide an attenuated form of a positive rail of the input signal to at least two nodes within the folded cascode transconductor and employing a feedforward path to provide an attenuated form of a negative rail of the input signal to at least two other nodes within the folded cascode transconductor. In a step 760, a second feedforward path may be employed to provide an attenuated form of the input signal to a node between an output of the transconductance amplifier gma and an input of a comparator. The method ends in an end step 770.

Those skilled in the art to which the invention relates will appreciate that other and further additions, deletions, substitutions and modifications may be made to the described embodiments without departing from the scope of the invention.

What is claimed is:

1. An active-passive continuous-time analog-to-digital converter having a signal input and comprising:
an input summing junction coupled to said signal input;
a folded cascode transconductor having an input coupled to said input summing junction; and
a feedforward path that couples said signal input to at least two nodes within said folded cascode transconductor.

2. The converter as recited in claim 1 wherein said feedforward path includes a feedforward resistor having a resistance value based on a maximum expected value of an input signal to be provided to said signal input.

3. The converter as recited in claim 1 wherein said feedforward path includes a feedforward resistor having a resistance value based on a reference current value associated with a node coupled to an output of said folded cascode transconductor.

4. The converter as recited in claim 1 wherein said converter is a differential active-passive continuous-time analog-to-digital converter, said feedforward path couples a positive rail of said signal input to said at least two nodes and said converter further comprises a feedforward path that couples a negative rail of said signal input to at least two other nodes within said folded cascode transconductor.

5. The converter as recited in claim 4 wherein said feedforward paths associated with said positive and negative rails include feedforward resistors of identical nominal resistance value.

6. The converter as recited in claim 1 further comprising a second feedforward path that includes a feedforward resistor and couples said signal input to a node between an output of the transconductance amplifier gma and an input of a comparator.

7. A method of continuous-time sigma-delta analog-to-digital conversion, comprising:
receiving an input signal into a signal input;
receiving said input signal into an input summing junction coupled to said signal input;
receiving said input signal into a folded cascode transconductor having an input coupled to said input summing junction; and
employing a feedforward path to provide an attenuated form of said input signal to at least two nodes within said folded cascode transconductor.

8. The method as recited in claim 7 wherein said feedforward path includes a feedforward resistor having a resistance value based on a maximum expected value of an input signal to be provided to said signal input.

9. The method as recited in claim 7 wherein said feedforward path includes a feedforward resistor having a resistance value based on a reference current value associated with a node coupled to an output of said folded cascode transconductor.

10. The method as recited in claim 7 wherein said employing comprises employing said feedforward path to provide an attenuated form of a positive rail of said input signal to at least two nodes within said folded cascode transconductor, said method further comprising employing a feedforward path to provide an attenuated form of a negative rail of said input signal to at least two other nodes within said folded cascode transconductor.

11. The method as recited in claim 10 wherein said feedforward paths associated with said positive and negative rails include feedforward resistors of identical nominal resistance value.

12. The method as recited in claim 7 further comprising employing a second feedforward path to provide an attenuated form of said input signal to a node between an output of the transconductance amplifier gma and an input of a comparator.
